(19) United States
(12) Patent Application Publication
(10) Pub. No.: US 2024/0383376 A1
(43) Pub. Date: Nov. 21, 2024

(54) APPARATUS FOR DIAGNOSING BATTERY AND METHOD THEREOF

(71) Applicants: HYUNDAI MOTOR COMPANY, Seoul (KR); Kia Corporation, Seoul (KR)

(72) Inventor: Hyun Soo PARK, Seoul (KR)

(73) Assignees: HYUNDAI MOTOR COMPANY, Seoul (KR); Kia Corporation, Seoul (KR)

(21) Appl. No.: 18/371,462

(22) Filed: Sep. 22, 2023

(30) Foreign Application Priority Data
May 15, 2023 (KR) 10-2023-0034065

(51) Int. Cl. B60L 58/22; B60L 53/80; G01R 31/388; G01R 31/396

(52) U.S. Cl. CPC B60L 58/22; B60L 53/80; G01R 31/388; G01R 31/396; B60L 58/40

(57) ABSTRACT

An apparatus for diagnosing a battery includes a plurality of battery modules, sensing units respectively matched with the battery modules on a one-to-one basis and that detect voltages of the battery modules and a processor which is configured to detect a replacement module provided for replacement among the battery modules, enters a first diagnosis mode based on detection of the replacement module to distinguish a replacement group including the replacement module and a reference group including battery modules other than the replacement module among the battery modules, and is configured to determine battery cell performance of the reference group and battery cell performance of the replacement group separately from the battery cell performance from the reference group in the first diagnosis mode.

### CROSS-REFERENCE TO RELATED APPLICATION

The present application claims priority to Korean Patent Application No. 10-2023-0034065, filed on Mar. 15, 2023, the entire contents of which is incorporated herein for all purposes by this reference.

### BACKGROUND OF THE PRESENT DISCLOSURE

### Field of the Present Disclosure

The present disclosure relates to an apparatus for diagnosing a battery and a method thereof, and more particularly, to a technology for diagnosing a battery for an electric vehicle.

### Description of Related Art

An eco-friendly vehicle that utilizes electrical energy as a power source, such as an electric vehicle or a hybrid vehicle, is provided with a battery for storing and outputting electrical energy. A battery includes a plurality of battery modules, and each of the battery modules may include a plurality of battery cells. A voltage deviation occurs between battery cells due to a structure, a performance distribution between cells, a difference in deterioration, and the like, and the voltage deviation reduces power available to the battery. Therefore, it is desirable to constantly maintain the voltage of the battery modules at a predetermined level to increase the efficiency of the vehicle battery.

Meanwhile, when a battery module is defective, some modules may be replaced with new modules. When the state of the battery is diagnosed after some modules of the battery have been replaced, it is highly likely determined that the battery modules are in an abnormal state due to a voltage deviation between the replaced battery module and the existing battery module. That is, when some battery modules are replaced, the battery system is determined to be defective as a whole due to a voltage deviation between the modules, and an alarm may be generated unnecessarily. To prevent the above phenomenon, when some battery modules are replaced, inconvenience is caused in that voltage balancing between the modules needs to be performed separately before the battery is provided in the vehicle.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus for diagnosing a battery configured for more efficiently determining battery performance even when some modules of a battery are replaced and a method thereof.

Furthermore, another aspect of the present disclosure provides an apparatus for diagnosing a battery configured for stably entering a process for performing voltage balancing between battery modules when some modules of a battery are replaced and a method thereof.

Furthermore, yet another aspect of the present disclosure provides an apparatus for diagnosing a battery configured for completing voltage balancing of battery modules more rapidly when some modules of a battery are replaced and a method thereof.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for diagnosing a battery includes a plurality of battery modules, sensing units respectively matched with the battery modules on a one-to-one basis and configured to detect voltages of the battery modules and a processor which is configured to detect a replacement module provided for replacement among the battery modules, enters a first diagnosis mode based on detection of the replacement module to distinguish a replacement group including the replacement module and a reference group including battery modules other than the replacement module among the battery modules, and is configured to determine battery cell performance of the reference group and battery cell performance of the replacement group separately from the battery cell performance from the reference group in the first diagnosis mode.

According to an exemplary embodiment of the present disclosure, the processor is configured to transmit identification numbers to the sensing units, receive the identification numbers from the sensing units, and determine an unidentified battery module matched with an unidentified sensing unit which does not transmit an identification number among the sensing units, as the replacement module.

According to an exemplary embodiment of the present disclosure, the processor is configured to determine the battery cell performance of the reference group and perform voltage balancing to reduce a voltage deviation between the reference group and the replacement group after determining the battery cell performance of the replacement group separately from the reference group in the first diagnosis mode.

According to an exemplary embodiment of the present disclosure, the processor is configured to determine a representative voltage value of the reference group and a representative voltage value of the replacement group and perform the voltage balancing to reduce the voltage deviation between the reference group and the replacement group when a deviation between the representative voltage value of the reference group and the representative voltage value of the replacement group is greater than or equal to a preset first threshold voltage.

According to an exemplary embodiment of the present disclosure, the processor may skip a process of performing diagnosis as to whether external factors affecting sensing voltages of the battery modules are in normal states and perform the voltage balancing.

According to an exemplary embodiment of the present disclosure, the processor may maintain an active state even after ignition-off.

According to an exemplary embodiment of the present disclosure, the processor may assign identification numbers to battery modules of the replacement group after the voltage balancing has been performed.

According to an exemplary embodiment of the present disclosure, the processor may enter a second diagnosis mode based on no detection of the replacement module and perform voltage balancing to improve a voltage deviation between the battery modules.

According to an exemplary embodiment of the present disclosure, the processor is configured to determine whether external factors affecting sensing voltages of the battery modules are in normal states and perform the voltage balancing after the processor concludes that a voltage deviation between the battery modules exceeds a preset second threshold voltage and the external factors are in normal states.

According to an exemplary embodiment of the present disclosure, the processor is configured to stop voltage balancing when ignition-off is detected.

According to an aspect of the present disclosure, a method for diagnosing a battery includes detecting, by a processor, a replacement module provided for replacement among battery modules, entering, by the processor, a first diagnosis mode based on detection of the replacement module to distinguish a replacement group including the replacement module and a reference group including battery modules other than the replacement module among the battery modules, and performing, by the processor, battery module diagnosis to determine battery cell performance of the reference group and battery cell performance of the replacement group separately from the battery cell performance from the reference group in the first diagnosis mode.

According to an exemplary embodiment of the present disclosure, the detecting of the replacement module may include transmitting, by the processor, identification numbers to sensing units matched with the battery modules on a one-to-one basis, receiving, by the processor, the identification numbers from the sensing units, and determining, by the processor, an unidentified battery module matched with an unidentified sensing unit which does not transmit an identification number among the sensing units, as the replacement module.

According to an exemplary embodiment of the present disclosure, the performing of the battery module diagnosis in the first diagnosis mode may include performing voltage balancing to reduce a voltage deviation between the reference group and the replacement group.

According to an exemplary embodiment of the present disclosure, the performing of the voltage balancing in the first diagnosis mode may include determining a representative voltage value of the reference group, determining a representative voltage value of the replacement group, determining a representative value deviation between the representative voltage value of the reference group and the representative voltage value of the replacement group, and reducing a voltage deviation between the reference group and the replacement group when the representative value deviation is greater than or equal to a preset first threshold voltage.

According to an exemplary embodiment of the present disclosure, the performing of the voltage balancing in the first diagnosis mode may further include skipping, by the processor a process of performing diagnosis as to whether external factors affecting sensing voltages of the battery modules are in normal states.

According to an exemplary embodiment of the present disclosure, the performing of the voltage balancing in the first diagnosis mode may include monitoring whether an ignition-off is entered, and maintaining an active state of the processor even after the ignition-off has been entered.

According to an exemplary embodiment of the present disclosure, the method may further include assigning identification numbers to battery modules of the replacement group after the voltage balancing in the first diagnosis mode has been performed.

According to an exemplary embodiment of the present disclosure, the method may further include entering a second diagnosis mode based on no detection of the replacement module and performing voltage balancing to improve a voltage deviation between the battery modules.

According to an exemplary embodiment of the present disclosure, the performing of the voltage balancing in the second diagnosis mode may further include performing, by the processor, diagnosis as to whether external factors affecting sensing voltages of the battery modules are in normal states, and the voltage balancing is performed when it is identified that the voltage deviation between the battery modules exceeds a preset second threshold voltage and the external factors are in normal states.

According to an exemplary embodiment of the present disclosure, the performing of the voltage balancing in the second diagnosis mode may include monitoring whether an ignition-off is entered, and stopping the voltage balancing based on the ignition-off.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram showing a configuration of a fuel cell system including an apparatus for diagnosing a battery according to an exemplary embodiment of the present disclosure.

FIG. 2 is a diagram showing a configuration of a battery device;

FIG. 3 is a diagram showing a configuration of a battery module;

FIG. 4 is a flowchart for describing a method of diagnosing a battery according to an exemplary embodiment of the present disclosure;

FIG. 5 is a flowchart for describing a method of detecting a replacement module according to an exemplary embodiment of the present disclosure;

FIG. 6 is a schematic diagram illustrating a process of detecting a replacement module;

FIG. 7 is a diagram for describing a method for determining the performance of a battery cell.

FIG. 8 is a flowchart for describing a method of diagnosing a battery according to another exemplary embodiment of the present disclosure;

FIG. 9 is a flowchart for describing timing in which voltage balancing process end portions;

FIG. 10 is a diagram for describing a method of diagnosing a battery according to another exemplary embodiment of the present disclosure; and

FIG. 11 is a diagram illustrating a computing system according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, various exemplary embodiments of the present disclosure will be described in detail with reference to the exemplary drawings. In adding the reference numerals to the components of each drawing, it should be noted that the identical or equivalent component is designated by the identical numeral even when they are displayed on other drawings. Furthermore, in describing the exemplary embodiment of the present disclosure, a detailed description of well-known features or functions will be ruled out in order not to unnecessarily obscure the gist of the present disclosure.

In describing the components of the exemplary embodiment of the present disclosure, terms such as first, second, “A”, “B”, (a), (b), and the like may be used. These terms are merely intended to distinguish one component from another component, and the terms do not limit the nature, sequence or order of the constituent components. Unless otherwise defined, all terms used herein, including technical or scientific terms, include the same meanings as those generally understood by those skilled in the art to which the present disclosure pertains. Such terms as those defined in a generally used dictionary are to be interpreted as including meanings equal to the contextual meanings in the relevant field of art, and are not to be interpreted as including ideal or excessively formal meanings unless clearly defined as including such in the present application.

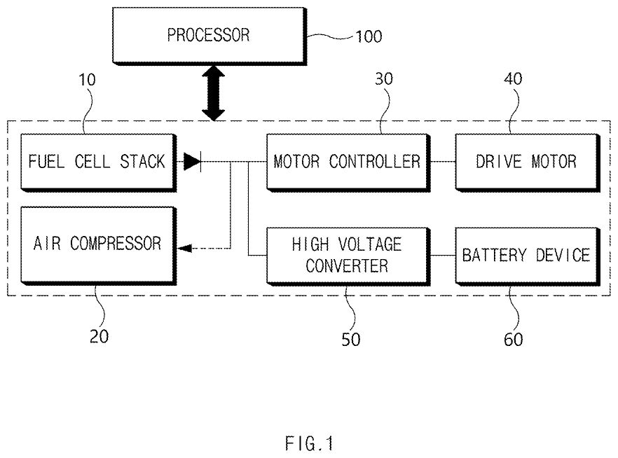

Hereinafter, various embodiments of the present disclosure will be described in detail with reference to FIGS. 1 to 10.

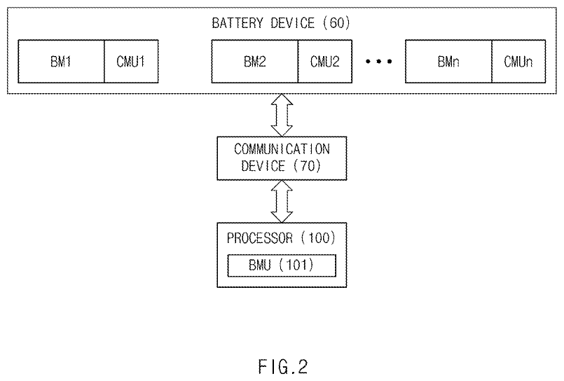

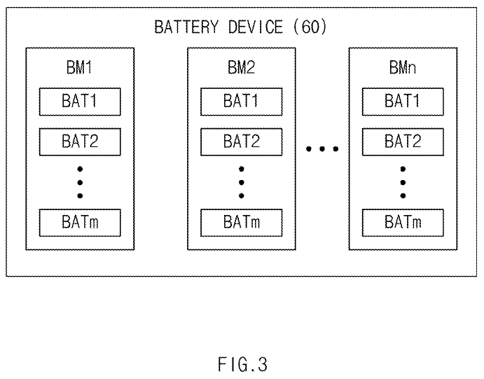

FIG. 1 is a diagram showing a configuration of a fuel cell system including an apparatus for diagnosing a battery according to an exemplary embodiment of the present disclosure. FIG. 2 is a diagram showing a configuration of a battery device, and FIG. 3 is a diagram showing a configuration of a battery module.

Referring to FIG. 1, FIG. 2, and FIG. 3, an apparatus for diagnosing a battery according to an exemplary embodiment of the present disclosure will be described below.

Referring to FIG. 1, an apparatus for diagnosing a battery according to an exemplary embodiment of the present disclosure may include a fuel cell stack 10, an air compressor 20, a motor controller 30, a drive motor 40, a high voltage converter 50, a battery device 60, a communication device 70 and a processor 100.

The fuel cell stack 10 may be configured to generate electrical energy by allowing fuel gas to electrochemically react with oxygen. The fuel cell stack 10 may include one or more unit cells, and the unit cell may receive hydrogen gas included in the fuel gas and air and generate electrical energy by inducing oxidation and reduction reactions. The unit cell may include a membrane-electrode assembly (MEA) protected by an end plate from the outside thereof and oxidizes/reduces hydrogen gas and air and at least one or more separators that supply fuel gas and air to the membrane-electrode assembly.

The air compressor 20 may supply compressed air to the fuel cell stack 100. To the present end, the air compressor 20 may include a motor that rotates a fan.

The motor controller 30 may be connected to the outputs of the fuel cell stack 10 and the battery device 60 through a main bus terminal and may phase-convert power supplied from the fuel cell stack 10 or the battery device 60 to drive the drive motor 40.

The drive motor 40 may be operated by the motor controller 30 and may receive power from the fuel cell stack 10 or the battery device 60 to drive a vehicle.

The high voltage converter 500 may be a bidirectional DC converter, and may be connected to a main bus terminal of the fuel cell stack 10 to control output of the fuel cell stack 10 and the battery device 60.

The battery device 60 may be charged with power provided by the fuel cell stack 10 and may be used as an auxiliary power source for the drive motor 40.

The battery device 60 may include first to n-th battery modules BM1 to BMn. Each of the battery modules BM1 to BMn may include a plurality of battery cells BAT1 to BATm. For example, the first battery module BM1 may include first to m-th battery cells BAT1 to BATm.

Cell monitoring units CMUs may be respectively coupled to the battery modules BM1 to BMn on a to one basis. The first CMU CMU1 may detect a voltage of the first battery module BM1 and may be referred to as a sensing unit. Furthermore, the first CMU CMU1 may receive and store an identification number for identifying the first battery module BM1 from the processor 100, and transmit the identification number to the processor 100 in response to a request from the processor 100.

The communication device 70 may be for communication between the CMUs and the processor 100, and may be implemented as a wired or wireless communication means. For example, the communication device 70 may support short-range communication by use of at least one of Bluetooth™, Radio Frequency Identification (RFID), Infrared Data Association (IrDA), Ultra Wideband (UWB), ZigBee, adjacent to Field Communication (NFC), Wireless-Fidelity (Wi-Fi), Wi-Fi Direct, and Wireless Universal Serial Bus (USB) technologies.

The processor 100 may correspond to an upper-level controller. The processor 100 may be configured for controlling the fuel cell system, and include a battery management unit (BMU) 101 that manages the battery module.

The processor 100 according to various exemplary embodiments of the present disclosure may detect a replacement module. The replacement module may refer to a module newly added to an area in the battery device 60 from which a certain battery module has been removed, or may be a module added through partial repair of the battery device 60 or the like.

The processor 100 may identify a diagnosis mode for determining battery performance based on whether a replacement module is detected. For example, the processor 100 may enter a first diagnosis mode when the replacement module is detected, and enter a second diagnosis mode when the replacement module is not detected.

In the first diagnosis mode, the processor 100 may be configured to determine battery cell performance of a reference group, and determine battery cell performance of a replacement group while distinguishing the replacement group from the reference group. The replacement group may refer to battery modules comprised of replacement modules, and the reference group may refer to battery modules other than the replacement group. A process of determining battery cell performance may include a process of performing voltage balancing to reduce a voltage deviation between a battery voltage of the reference group and a battery voltage of the replacement group.

In the first diagnosis mode, the processor 100 may obtain a representative voltage value of the reference group and a representative voltage value of the replacement group and determine a deviation between the representative voltage values to perform voltage balancing. As the representative voltage value, an average value, a maximum value, or a minimum value may be used.

In the first diagnosis mode, the processor 100 may be configured to determine whether the deviation between the representative voltage values is equal to or greater than a first threshold voltage to perform voltage balancing, and skip a process of determining abnormal conditions of external factors affecting voltage detecting of the battery modules.

In the first diagnosis mode, the processor 100 may continuously perform a voltage balancing process by maintaining an active state even when ignition is turned off in a state in which voltage balancing has not been completed.

Furthermore, in the second diagnosis mode, the processor 100 may be configured to determine a voltage deviation between battery modules and perform voltage balancing to reduce the voltage deviation between the battery modules.

In the second diagnosis mode, the processor 100 may be configured to determine whether the voltage deviation between the battery modules is equal to or greater than a second threshold voltage to perform voltage balancing and furthermore, determine abnormal conditions of external factors affecting voltage detecting of the battery modules. The processor 100 may not perform voltage balancing when external factors are abnormal, even when the voltage deviation between the battery modules is equal to or greater than the second threshold voltage.

In the second diagnosis mode, the processor 100 may end the voltage balancing process when the ignition is turned off in a state where voltage balancing has not been completed.

The processor 100 and the CMUs may include a memory for storing identification numbers and an algorithm for battery diagnosis. The memory may be implemented using a hard disk drive, flash memory, electrically erasable programmable read-only memory (EEPROM), static RAM (SRAM), ferro-electric RAM (FRAM), phase-change RAM (PRAM), magnetic RAM (MRAM), Dynamic Random Access (DRAM), Synchronous Dynamic Random Access Memory (SDRAM), Double Date Rate-SDRAM (DDR-SDRAM), and the like.

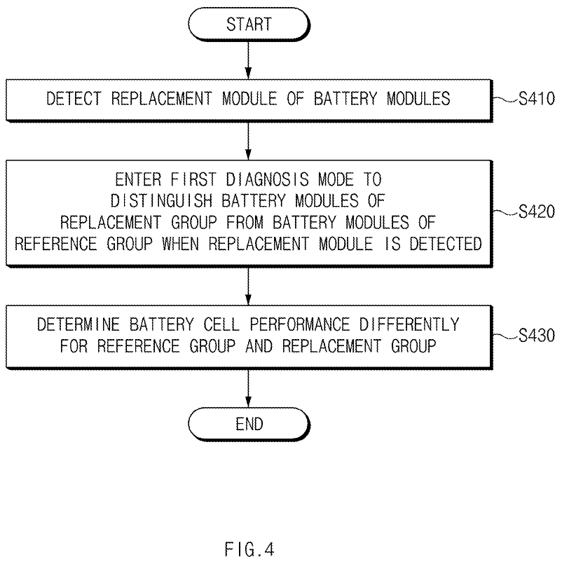

Hereinafter, a method of diagnosing a battery according to an exemplary embodiment of the present disclosure will be described with reference to FIG. 4. FIG. 4 is a flowchart for describing a method of diagnosing a battery according to an exemplary embodiment of the present disclosure. It may be understood that the method of diagnosing a battery shown in FIG. 4 is controlled by the processor shown in FIG. 1.

Referring to FIG. 4, in S410, the processor 100 may detect a replacement module among battery modules.

As shown in FIG. 2 and FIG. 3, the battery modules may refer to first to n-th battery modules BM1 to BMn included in the battery device 60.

The replacement module may refer to a newly added module when a certain module is replaced in the battery device 60. According to an exemplary embodiment of the present disclosure, the processor 100 may detect a replacement module based on identification numbers assigned to the battery modules BM1 to BMn on a one-to-one basis.

In S420, the processor 100 may enter a first diagnosis mode when the replacement module is detected. Also, the processor 100 may classify the battery modules into a replacement group and a reference group in the first diagnosis mode.

The replacement group may be a battery module group comprised of replacement modules. The reference group may be a battery module group comprised of remaining battery modules other than the replacement group among battery modules.

In S430, the processor 100 may be configured to determine battery cell performance of the replacement group separately from battery cell performance of the reference group.

For example, when the replacement group includes only the second battery module BM2, the processor 100 may be configured to determine the performance of a battery cell belonging to the second battery module BM2. Furthermore, the processor 100 may be configured to determine the performance of battery cells belonging to the other battery modules BM1 and BM3 to BMn other than the second battery module BM2.

The process for determining cell performance of battery modules in the first diagnosis mode may include a voltage balancing process for reducing a voltage deviation between the reference group and the replacement group.

The voltage balancing process may be performed when a deviation between a representative voltage value of the reference group and a representative voltage value of the replacement group is equal to or greater than a preset first threshold voltage. The representative voltage value may be determined as an average value, a maximum value, or a minimum value.

In step S430, the reference group and the replacement group may be identified to determine the cell performance, thus preventing an alarm related to abnormal determination from occurring unnecessarily. For example, when cell performance is determined without distinguishing between the reference group and the replacement group, an alarm indicating an abnormal determination is very likely to occur, because there is a large difference in cell voltage between the reference group and the replacement group. Therefore, when there is a battery module to be replaced, a warning alarm may occur with a very high probability.

On the other hand, when the cell performance of the replacement group is determined separately from the cell performance of the reference group, an alarm caused by a voltage deviation between the reference group and the replacement group may be removed in determining the cell performance.

Hereinafter, detailed embodiments of the processes shown in FIG. 4 will be described.

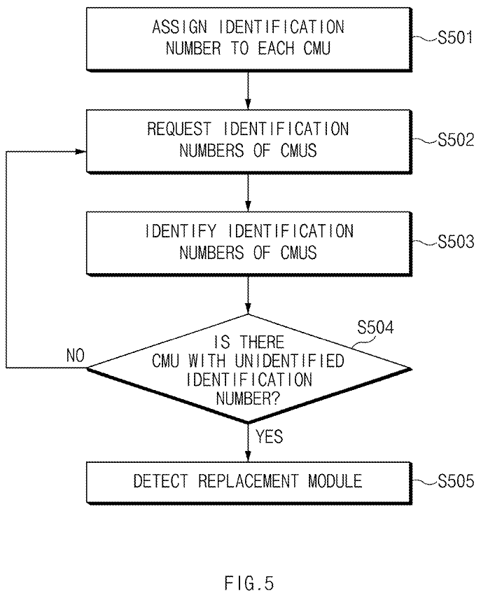

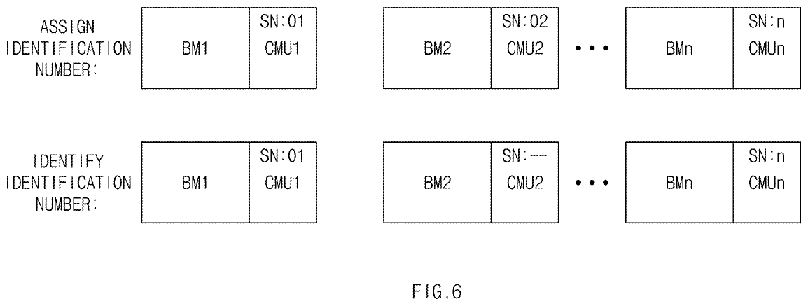

An exemplary embodiment of detecting a replacement module will be described with referenced to FIG. 5 and FIG. 6.

FIG. 5 is a flowchart for describing a method of detecting a replacement module according to an exemplary embodiment of the present disclosure, and FIG. 6 is a schematic diagram illustrating a process of detecting a replacement module.

Referring to FIG. 5 and FIG. 6, in S501, the processor 100 may assign identification numbers to CMUs CMU1 to CMUn.

To the present end, the processor 100 may transmit unique identification numbers (serial number; SN) to the CMUs (CMU1 to CMUn) through the communication device 70, respectively. For example, the processor 100 may transmit an identification number of “01” to the first CMU CMU1 and transmit an identification number of “02” to the second CMU CMU2. Similarly, an identification number of “n” may be assigned to the n-th CMU CMUn.

The processor 100 may store the identification numbers provided from the communication device 70 in a memory.

In S502, the processor 100 may request an identification number from the CMUs (CMU1 to CMUn).

The processor 100 may request the identification numbers from the CMUs (CMU1 to CMUn) based on a specific event, such as when ignition On (IG On) is started.

Alternatively, the processor 100 may request the identification numbers from the CMUs (CMU1 to CMUn) at regular intervals in the ignition-On state.

The CMUs (CMU1 to CMUn) may transmit the identification numbers stored in the memory in response to a request for the identification numbers from the processor 100.

In S503, the processor 100 may identify the identification numbers provided from the CMUs (CMU1 to CMUn).

In S504, the processor 100 may be configured to determine whether there is a CMU whose identification number is not identified.

In S505, the processor 100 may detect a CMU whose identification number is not identified as a replacement module. For example, when an identification number is not provided from the second CMU (CMU2) as shown in FIG. 6, the processor 100 may be configured to determine that the second CMU (CMU2) is a replacement module.

In S504, if there is a CMU with unidentified identification number, the S502 is repeated

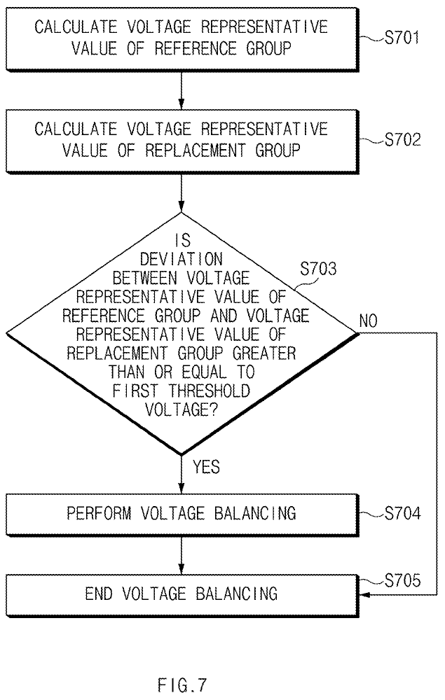

FIG. 7 is a diagram for describing a method of determining performance of a battery cell.

Referring to FIG. 7, a method of determining performance of a battery cell according to an exemplary embodiment of the present disclosure will be described.

In S701, the processor 100 may be configured to determine a representative voltage value of a reference group.

The processor 100 may obtain the representative voltage value by determining an average value of cell voltages of cells belonging to the reference group. For example, an average voltage of cells included in battery modules belonging to the reference group may be a representative voltage value. When the number of battery modules in the reference group is “n−1” and each battery module includes m cells, the processor 100 may obtain a representative value by determining an average voltage for “(n−1)×m” cells.

Alternatively, the processor 100 may obtain a maximum value or a minimum value among cell voltages of cells belonging to the reference group, as a representative voltage value.

In S702, the processor 100 may be configured to determine a representative voltage value of the replacement group.

The processor 100 may obtain a representative voltage value of the replacement group in the same method as the reference group. For example, the processor 100 may obtain the average voltage of cells belonging to the replacement group as a representative voltage value. Alternatively, the processor 100 may obtain a maximum value or a minimum value among cell voltages of cells belonging to the replacement group, as a representative voltage value.

In S703, the processor 100 may be configured to determine whether a deviation between the representative voltage value of the reference group and the representative voltage value of the replacement group is greater than or equal to a preset first threshold voltage.

In S704, when the deviation between the representative voltage value of the reference group and the representative voltage value of the replacement group is greater than or equal to a preset first threshold voltage, the processor 100 may perform voltage balancing.

The processor 100 may discharge voltages of high voltage cells for voltage balancing. For example, when the representative voltage value of the reference group is greater than the representative voltage value of the replacement group, the voltage difference between the reference group and the replacement group may be reduced by discharging the voltages of cells belonging to the reference group. On the other hand, when the representative voltage value of the reference group is smaller than the representative voltage value of the replacement group, the voltage difference between the reference group and the replacement group may be reduced by discharging the voltages of cells belonging to the replacement group.

In S705, the processor 100 may end voltage balancing when the representative voltage value of the reference group and the representative voltage value of the replacement group are within a predetermined range.

In S703, when the deviation between the representative voltage value of the reference group and the representative voltage value of the replacement group is not greater than or equal to a preset first threshold voltage, the processor 100 may end voltage balancing in S705.

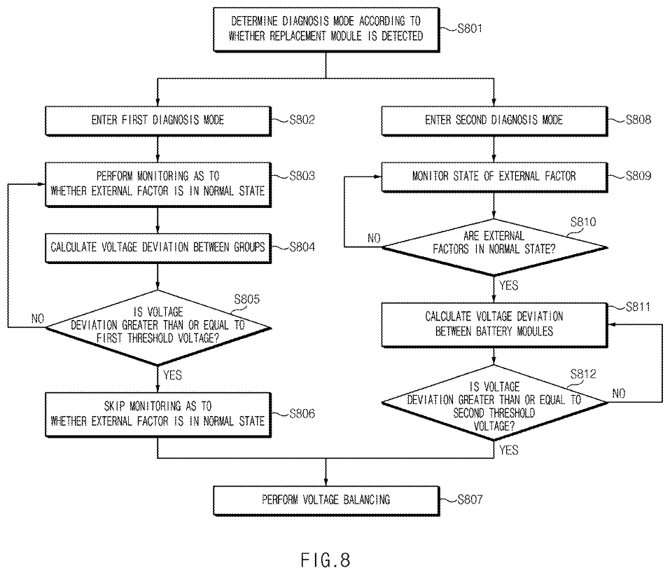

FIG. 8 is a flowchart for describing a method of diagnosing a battery according to another exemplary embodiment of the present disclosure. FIG. 8 illustrates a method of diagnosing a battery while focusing on voltage balancing process entry conditions according to diagnosis modes.

Referring to FIG. 8, in S801, the processor 100 may be configured to determine a diagnosis mode according to whether a replacement module is detected.

For example, the processor 100 may enter a first diagnosis mode when the replacement module is detected (S802), and enter a second diagnosis mode when the replacement module is not detected (S808).

In S803, when entering the first diagnosis mode, the processor 100 may monitor whether external factors are in normal states. The external factors may refer to factors which may affect a battery cell voltage, and may include relays, CMUs, BMUs, and the like.

In S804, the processor 100 may be configured to determine a voltage deviation between groups.

The processor 100 may use S701 and S702 shown in FIG. 7 to determine the voltage deviation between groups. For example, the processor 100 may be configured to determine a representative voltage value of battery cells belonging to a reference group and determine a representative voltage value of battery cells belonging to a replacement group. Furthermore, a deviation between the representative voltage values of battery cells belonging to the reference group and the representative voltage value of battery cells belonging to the replacement group may be determined.

In S805, the processor 100 may be configured to determine whether the voltage deviation is greater than or equal to a first threshold voltage.

For example, the processor 100 may be configured to determine whether a difference between the representative voltage value of the reference group and the representative voltage value of the replacement group is greater than or equal to a first threshold voltage.

In S806, when the difference between the representative voltage value of the reference group and the representative voltage value of the replacement group is greater than or equal to the first threshold voltage, the processor 100 may skip a process of monitoring whether the external factors are in normal states.

Because the first diagnosis mode is performed in a state where the replacement module is disposed in the battery modules, it may be highly likely that a voltage deviation between the replacement module and the reference module is large. That is, because it may be determined that voltage balancing is required in the first diagnosis mode, there may be no need to more precisely measure the voltage of the battery module. Accordingly, the processor 100 may skip a process for determining whether the external factors are in normal states to more precisely measure the voltage of the battery module. As a result, the processor 100 may enter a process for performing voltage balancing in S807 even when external factors are in abnormal states.

In S806, when the difference between the representative voltage value of the reference group and the representative voltage value of the replacement group is not greater than or equal to the first threshold voltage, the process will go back to S803. In S807, the processor 100 may perform voltage balancing.

The processor 100 may perform voltage balancing to reduce a difference between the representative voltage value of the reference group and the representative voltage value of the replacement group.

In S808, when the replacement module is not detected, the processor 100 may enter a second diagnosis mode.

In S809 and S810, the processor 100 may monitor the state of the external factors and determine whether the external factors are in normal states.

For example, the processor 100 may be configured to determine whether external factors which may affect a measured value during a process of measuring a battery cell voltage, such as a relay, a CMU or a BMU, are in normal states.

In S810, if the external factors are not in normal state, the process will go back to S809.

In S811 and S812, the processor 100 may be configured to determine a voltage deviation between battery modules.

The processor 100 may compare an average voltage of cells included in the battery modules with an average voltage of each battery module. For example, the average voltage of the first battery module may be compared with the average voltage of all battery modules, and the average voltage of the second battery module may be compared with the average voltage of all battery modules. In the present way, it is possible to compare the average voltage of each battery module with the average voltage of all battery modules, and determine whether a difference between the average voltage of a certain battery module and the average voltage of all battery modules is equal to or greater than a second threshold voltage.

In S812, if a difference between the average voltage of a certain battery module and the average voltage of all battery modules is not equal to or greater than a second threshold voltage, the process will go back to S811.

The processor 100 may enter a voltage balancing process (S807) when the voltage deviation between the battery modules is greater than or equal to the second threshold voltage.

As a result, the processor 100 may perform the voltage balancing process only when external factors between battery modules as well as voltage deviations are in normal states. Because the second diagnosis mode is performed when there is no replacement module, the voltage balancing procedure may not be required, and there is a need to more precisely measure the voltages of the battery modules to enter the voltage balancing process. Accordingly, in the second diagnosis mode, the processor 100 may include a process for determining whether or not there is an error in a process of measuring the voltages of the battery modules by determining whether the external factors are in abnormal states.

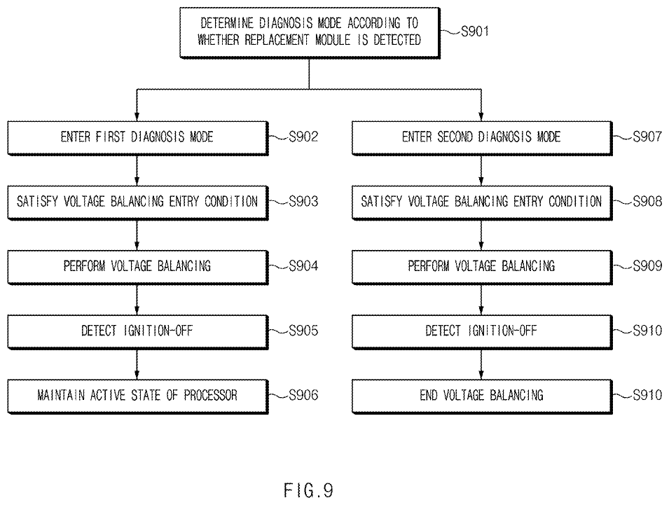

FIG. 9 is a flowchart for describing timing in which voltage balancing process end portions. Referring to FIG. 9, the timing in which voltage balancing process end portions will be described below.

In S901, the processor 100 may be configured to determine a diagnosis mode according to whether a replacement module is detected.

For example, the processor 100 may enter a first diagnosis mode when the replacement module is detected (S902), and enter a second diagnosis mode when the replacement module is not detected (S907).

In S903 and S904, the processor 100 may be configured to determine a voltage balancing entry condition in a first diagnosis mode state and perform voltage balancing. In the first diagnosis mode, the voltage balancing entry condition may be a state in which a voltage deviation between the reference module and the replacement module is greater than or equal to a first threshold voltage.

In S905, the processor 100 may detect ignition-off. The ignition-off may be a signal indicating that the ignition of the vehicle is turned off.

In S906, the processor 100 may maintain an active state when the ignition-off is detected. That is, the processor 100 may enter an inactive state according to ignition-off in a general state, but maintain an active state in a state in which voltage balancing is performed in the first diagnosis mode. Accordingly, the processor 100 may continuously perform the voltage balancing process while maintaining an active state even in the ignition-off state.

S906 may include maintaining active states of controllers and devices involved in a voltage balancing process in addition to the processor 100. For example, means for controlling discharge of the battery module for voltage balancing may maintain an active state.

In S908 and S909, in the second diagnosis mode, the processor 100 may be configured to determine a voltage balancing entry condition and perform voltage balancing.

In the second diagnosis mode, the voltage balancing entry condition may be a condition that a voltage deviation between battery modules is greater than or equal to a second threshold voltage, and external factors are determined to be in normal states.

In steps S910 and S911, the processor 100 may end voltage balancing when detecting ignition-off.

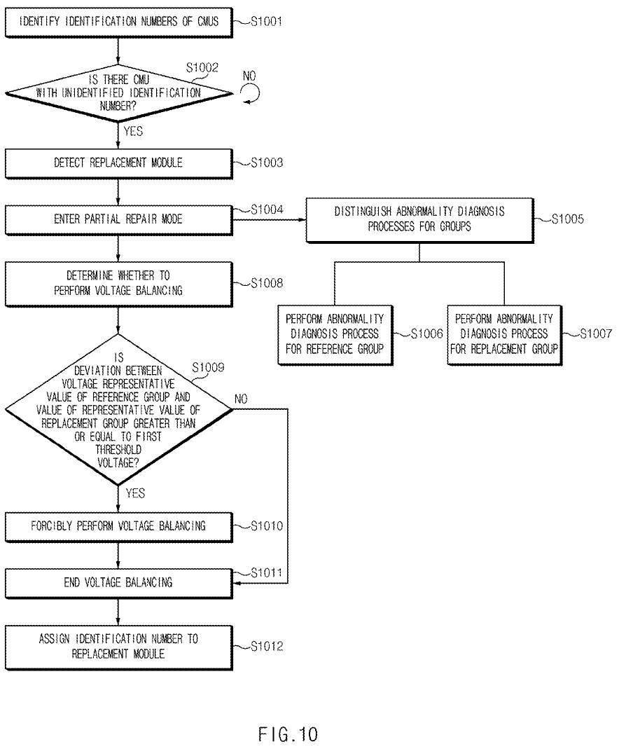

FIG. 10 is a diagram for describing a method of diagnosing a battery according to another exemplary embodiment of the present disclosure. FIG. 10 illustrates a process of performing voltage balancing after separating a process of performing abnormality diagnosis according to a detected replacement module.

Referring to FIG. 10, a method of diagnosing a battery according to another exemplary embodiment of the present disclosure will be described below.

In S1001, the processor 100 may identify the identification numbers provided from the CMUs (CMU1 to CMUn). To the present end, the CMUs (CMU1 to CMUn) may have stored identification numbers transmitted from the processor 100 in advance.

In S1002, the processor 100 may be configured to determine whether there is a CMU whose identification number is not identified.

In S1003, the processor 100 may detect a CMU whose identification number is not identified as a replacement module.

In S1004, when the replacement module is detected, a partial repair mode may be entered. The partial repair mode may include S1005, S1006, and S1007 to be described later.

In S1005, when the partial repair mode is entered, the processor 100 may separate a process of performing abnormality diagnosis by group. The process of diagnosing a battery abnormality in S1006 and S1007 may include a process for determining whether a voltage deviation between battery cells is equal to or greater than a predetermined level.

In step S1006, the processor 100 may diagnose abnormality of a reference group. That is, the processor 100 may perform battery abnormality diagnosis on only battery modules that are not replaced. For example, when a deviation between the highest voltage and the smallest voltage among the voltages of the battery cells of the reference group is equal to or greater than a predetermined level, the processor 100 may be configured to determine that the voltage deviation of the reference group is abnormal.

In S1007, the processor 100 may perform abnormality diagnosis on the replacement group. The processor 100 may perform battery abnormality diagnosis on only the battery modules belonging to the replacement group. For example, when a deviation between the highest voltage and the smallest voltage among the voltages of the battery cells belonging to the replacement group is equal to or greater than a predetermined level, the processor 100 may be configured to determine that the voltage deviation of the reference group is abnormal.

In S1008 and S1009, the processor 100 may be configured to determine whether to perform voltage balancing. For example, the processor 100 may be configured to determine whether a deviation between a representative voltage value of the reference group and a representative voltage value of the replacement group is greater than or equal to a preset first threshold voltage.

In S1010, when the deviation between the representative voltage value of the reference group and the representative voltage value of the replacement group is greater than or equal to the preset first threshold voltage, the processor 100 may perform voltage balancing.

In S1010, which proceeds based on the detection of the replacement module, the processor 100 may skip a process for monitoring whether an external factor is in a normal state. That is, the processor 100 may perform voltage balancing based on a result of the determination in step S1009 regardless of whether external factors which may affect the battery cell voltage are in normal states.

In S1011, the processor 100 may end voltage balancing when the representative voltage value of the reference group and the representative voltage value of the replacement group are within a predetermined range.

In S1009, if the S1009 is not met, the process will go to the S1011.

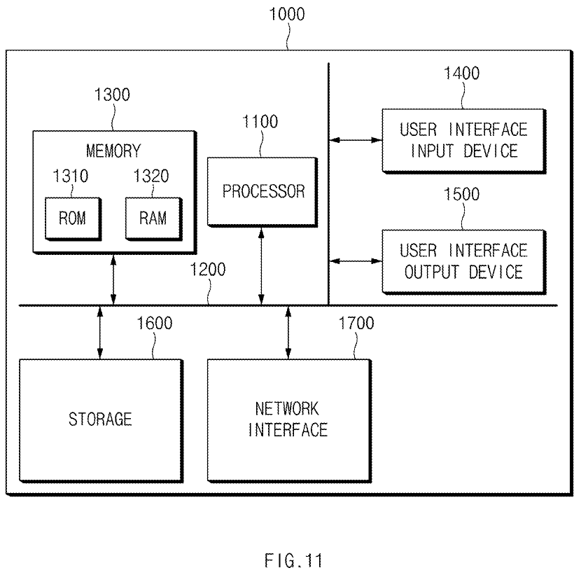

In S1012, the processor 100 may assign an identification number to the replacement module. FIG. 11 illustrates a computing system according to an exemplary embodiment of the present disclosure.

Referring to FIG. 11, a computing system 1000 may include at least one processor 1100, a memory 1300, a user interface input device 1400, a user interface output device 1500, storage 1600, and a network interface 1700, which are connected to each other via a bus 1200.

The processor 1100 may be a central processing unit (CPU) or a semiconductor device that processes instructions stored in the memory 1300 and/or the storage 1600. The memory 1300 and the storage 1600 may include various types of volatile or non-volatile storage media. For example, the memory 1300 may include a Read Only Memory (ROM) and a Random Access Memory (RAM).

Thus, the operations of the method or the algorithm described in connection with the exemplary embodiments included herein may be embodied directly in hardware or a software module executed by the processor 1100, or in a combination thereof. The software module may reside on a storage medium (that is, the memory 1300 and/or the storage 1600) such as a RAM, a flash memory, a ROM, an EPROM, an EEPROM, a register, a hard disk, a removable disk, and a CD-ROM.

The exemplary storage medium may be coupled to the processor 1100, and the processor 1100 may read information out of the storage medium and may record information in the storage medium. Alternatively, the storage medium may be integrated with the processor 1100. The processor and the storage medium may reside in an application specific integrated circuit (ASIC). The ASIC may reside within a user terminal. In another case, the processor and the storage medium may reside in the user terminal as separate components.

The above description is merely illustrative of the technical idea of the present disclosure, and various modifications and variations may be made without departing from the essential characteristics of the present disclosure by those skilled in the art to which the present disclosure pertains.

Therefore, the exemplary embodiments of the present disclosure are provided to explain the spirit and scope of the present disclosure, but not to limit them, so that the spirit and scope of the present disclosure is not limited by the embodiments. The scope of protection of the present disclosure should be interpreted by the following claims, and all technical ideas within the scope equivalent thereto should be construed as being included in the scope of the present disclosure.

According to an exemplary embodiment of the present disclosure, it is possible to prevent unnecessary failure diagnosis by performing performance evaluation by distinguishing a replacement module from a battery module other than the replacement module.

Furthermore, according to an exemplary embodiment of the present disclosure, when some modules of the battery are replaced, voltage balancing is performed without considering external factors affecting the battery voltage measurement, rapidly solving the deviation voltage of the battery module with a large voltage deviation due to the replacement module.

Furthermore, according to an exemplary embodiment of the present disclosure, when some modules of a battery are replaced, voltage balancing of battery modules may be completed more rapidly by continuously performing voltage balancing even in an ignition-off situation.

Furthermore, various effects may be provided that are directly or indirectly understood through the present disclosure.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of one or more of A and B”. In addition, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An apparatus for diagnosing a battery, the apparatus comprising:
a plurality of battery modules;
sensing units respectively matched with the battery modules on a one-to-one basis and configured to detect voltages of the battery modules; and
a processor configured to:
detect a replacement module provided for replacement among the battery modules,
enter a first diagnosis mode based on detection of the replacement module to distinguish a replacement group including the replacement module and a reference group including battery modules other than the replacement module among the battery modules, and
determine battery cell performance of the reference group and battery cell performance of the replacement group separately from the battery cell performance from the reference group in the first diagnosis mode.

2. The apparatus of claim 1, wherein the processor is further configured to:
transmit identification numbers to the sensing units,
receive the identification numbers from the sensing units, and
determine an unidentified battery module matched with an unidentified sensing unit which does not transmit an identification number among the sensing units, as the replacement module.

3. The apparatus of claim 1, wherein the processor is further configured to determine the battery cell performance of the reference group and to perform voltage balancing to reduce a voltage deviation between the reference group and the replacement group after determining the battery cell performance of the replacement group separately from the reference group in the first diagnosis mode.

4. The apparatus of claim 3, wherein the processor is further configured to:
determine a representative voltage value of the reference group and a representative voltage value of the replacement group, and
perform the voltage balancing to reduce the voltage deviation between the reference group and the replacement group when a deviation between the representative voltage value of the reference group and the representative voltage value of the replacement group is greater than or equal to a preset first threshold voltage.

5. The apparatus of claim 4, wherein the processor is further configured to skip a process of performing diagnosis as to whether external factors affecting sensing voltages of the battery modules are in normal states and to perform the voltage balancing.

6. The apparatus of claim 5, wherein the processor is further configured to maintain an active state even after ignition-off.

7. The apparatus of claim 3, wherein the processor is further configured to assign identification numbers to battery modules of the replacement group after the voltage balancing has been performed.

8. The apparatus of claim 1, wherein the processor is further configured to enter a second diagnosis mode based on no detection of the replacement module and to perform voltage balancing to improve a voltage deviation between the battery modules.

9. The apparatus of claim 8, wherein the processor is further configured to:
determine whether external factors affecting sensing voltages of the battery modules are in normal states, and
perform the voltage balancing after the processor concludes that a voltage deviation between the battery modules exceeds a preset second threshold voltage and the external factors are in the normal states.

10. The apparatus of claim 8, wherein the processor is further configured to stop voltage balancing when ignition-off is detected.

11. A method for diagnosing a battery, the method comprising:
detecting, by a processor, a replacement module provided for replacement among battery modules;
entering, by the processor, a first diagnosis mode based on detection of the replacement module to distinguish a replacement group including the replacement module and a reference group including battery modules other than the replacement module among the battery modules; and
performing, by the processor, battery module diagnosis to determine battery cell performance of the reference group and battery cell performance of the replacement group separately from the battery cell performance from the reference group in the first diagnosis mode.

12. The method of claim 11, wherein the detecting of the replacement module includes
transmitting, by the processor, identification numbers to sensing units matched with the battery modules on a one-to-one basis;
receiving, by the processor, the identification numbers from the sensing units; and
determining, by the processor, an unidentified battery module matched with an unidentified sensing unit which does not transmit an identification number among the sensing units, as the replacement module.

13. The method of claim 11, wherein the performing of the battery module diagnosis in the first diagnosis mode includes:
performing voltage balancing to reduce a voltage deviation between the reference group and the replacement group.

14. The method of claim 13, wherein the performing of the voltage balancing in the first diagnosis mode includes:
determining a representative voltage value of the reference group;
determining a representative voltage value of the replacement group;
determining a representative value deviation between the representative voltage value of the reference group and the representative voltage value of the replacement group; and
reducing a voltage deviation between the reference group and the replacement group when the representative value deviation is greater than or equal to a preset first threshold voltage.

15. The method of claim 14, wherein the performing of the voltage balancing in the first diagnosis mode includes:
skipping, by the processor, a process of performing diagnosis as to whether external factors affecting sensing voltages of the battery modules are in normal states.

16. The method of claim 15, wherein the performing of the voltage balancing in the first diagnosis mode includes:
monitoring whether an ignition-off is entered; and
maintaining an active state of the processor even after the ignition-off has been entered.

17. The method of claim 13, further including:
assigning, by the processor, identification numbers to battery modules of the replacement group after the voltage balancing in the first diagnosis mode has been performed.

18. The method of claim 11, further including:
entering, by the processor, a second diagnosis mode based on no detection of the replacement module and performing voltage balancing to improve a voltage deviation between the battery modules.

19. The method of claim 18,
wherein the performing of the voltage balancing in the second diagnosis mode further includes performing, by the processor, diagnosis as to whether external factors affecting sensing voltages of the battery modules are in normal states, and
wherein the voltage balancing is performed when the processor concludes that the voltage deviation between the battery modules exceeds a preset second threshold voltage and the external factors are in the normal states.

20. The method of claim 18, wherein the performing of the voltage balancing in the second diagnosis mode includes
monitoring whether an ignition-off is entered; and
stopping the voltage balancing based on the ignition-off.
